(19) United States
(12) Patent Application Publication
(10) Pub. No.: US 2023/0115689 A1
(43) Pub. Date: Apr. 13, 2023

(54) STAIR STEP FRAME STRUCTURES IN PIEZOELECTRIC RESONATORS

(71) Applicant: TEXAS INSTRUMENTS INCORPORATED, Dallas, TX (US)

(72) Inventors: Steffen Paul Link, Urbana, IL (US); Ting-Ta Yen, San Jose, CA (US); Jeronimo Segovia-Fernandez, San Jose, CA (US)

(21) Appl. No.: 17/488,891

(22) Filed: Sep. 29, 2021

(51) Int. Cl. H03H 9/02; H03H 9/17; H03H 3/02

(52) U.S. Cl. CPC H03H 9/0211; H03H 3/02; H03H 9/17

(57) ABSTRACT

A piezoelectric resonator includes a first conductive layer, and a piezoelectric layer affixed to a first side of the first conductive layer. The piezoelectric resonator also includes a stair step frame structure affixed to a first side of the piezoelectric layer, and a second conductive layer, affixed to the first side of the piezoelectric layer and covering the stair step frame structure.

### BACKGROUND

Bulk acoustic wave (BAW) resonators are electromechanical devices in which standing acoustic waves are generated by an electrical signal in the bulk of a piezoelectric material. Quartz (SiO₂), aluminum nitride (AlN), and zinc oxide (ZnO) are commonly used as piezoelectric materials in BAW resonators. Simple BAW resonators comprise a thin slice of the piezoelectric material between two electrodes which are used to produce the electrical signal in the bulk of the piezoelectric material.

A desired frequency is obtained by selecting a piezoelectric material based on its natural frequency and specifying the thickness of the piezoelectric material to obtain the desired frequency. More complex BAW resonators use more complex designs.

BAW resonators are commonly used in communication equipment within high-Qₚ (quality factor), narrow band-pass filters that are useful particularly in wireless devices operating in crowded frequency ranges. BAW resonators are also used as frequency references in timing devices such as oscillators with a stable output frequency. Whereas, surface acoustic wave (SAW) resonators are useful up to approximately 1.5 GHz, BAW resonators are more efficient at the higher frequencies of 2 GHz to approximately 10 GHz. In addition to radio frequency (RF) filters and duplexers in wireless communication devices, and oscillators for timing applications, BAW resonators are also used within a wide variety of sensors.

### SUMMARY

In an implementation, a piezoelectric resonator includes a first conductive layer, and a piezoelectric layer affixed to a first side of the first conductive layer. The piezoelectric resonator also includes a stair step frame structure affixed to a first side of the piezoelectric layer, and a second conductive layer, affixed to the first side of the piezoelectric layer and covering the stair step frame structure.

In another implementation, a method of forming a piezoelectric resonator includes forming a low impedance layer on a first side of a substrate, and forming a first conductive layer on the low impedance layer. The method also includes forming a piezoelectric layer on the first conductive layer, forming a stair step frame structure on the piezoelectric layer, and forming a second conductive layer, on the piezoelectric layer covering the stair step frame structure.

In a further implementation, a bulk acoustic wave resonator (BAW) module includes a package, and a piezoelectric resonator within the package. The piezoelectric resonator includes a first conductive layer, and a piezoelectric layer affixed to a first side of the first conductive layer. The piezoelectric resonator also includes a stair step frame structure affixed to a first side of the piezoelectric layer, and a second conductive layer, affixed to the first side of the piezoelectric layer and covering the stair step frame structure.

### BRIEF DESCRIPTION OF THE DRAWINGS

FIGS. 1A-1C illustrate a conventional BAW resonator in an example implementation.

FIGS. 2A-2C illustrate cross-sections of example BAW resonators including stair step frames in example implementations.

FIG. 3 illustrates a cross-section of an example stair step frame within a BAW resonator including multiple steps.

FIGS. 4A and 4B illustrate cross-sections of an example stair step frame within a BAW resonator including a single step.

FIG. 5A illustrates a cross-section of a conventional FBAR including a frame.

FIG. 5B illustrates a cross-section of an FBAR including multiple concentric stair stepped frames.

FIG. 6 illustrates the frequency response of an example BAW resonator including stair step frames.

FIG. 7 illustrates a BAW resonator module in an example implementation.

FIG. 8 illustrates a flow chart of a method of forming a piezoelectric resonator in an example implementation.

### DETAILED DESCRIPTION

Currently there are two common configurations for BAW resonators. Thin film bulk acoustic wave Resonators (TFBARs or FBARs) are manufactured using thin film technologies are either edge supported or composite. Solidly mounted resonators (SMRs) are disposed on a solid substrate such as a silicon wafer. In some embodiments SMRs include additional reflective layers (called Bragg reflectors) between the BAW resonator device and the substrate in order to minimize leakage of the acoustic wave into the substrate. In some designs, Bragg reflectors are introduced on top of the BAW resonator to also minimize leakage of the acoustic wave into the package materials, such as mold compound. These SMRs including additional reflective layers are called dual-Bragg acoustic resonators (DBARs).

In designing BAW resonator modules, a number of material considerations must be considered. Since the resonant frequency of BAW resonator devices is determined by the dimensions of very thin piezoelectric materials, it is critical that those materials maintain their dimensions over long term use in a wide variety of conditions.

In thickness mode piezoelectric resonators, such as bulk acoustic wave resonators (BAWs), solidly mounted resonators (SMRs), film bulk acoustic resonators (FBARs), and dual-Bragg acoustic resonators (DBARs), the confinement of energy around the second, or parallel, resonance frequency (fₚ) is important to the quality factor (Qₚ) of the resonance. In particular design of the bounds of the thickness mode piezoelectric resonator plays an important part in increasing Qₚ as well as subduing unwanted modes in the lateral direction. These modes leak additional energy out of the resonator lowering Qₚ and have undesirable effects on the functioning of the resonator. Frames are used to create a “piston” mode shape, but often fail to achieve this due to edge effects of the device.

Various example embodiments and configurations of stair step frames within BAW resonator modules configured to increase the quality factor (Qₚ) of BAW resonators are described herein.

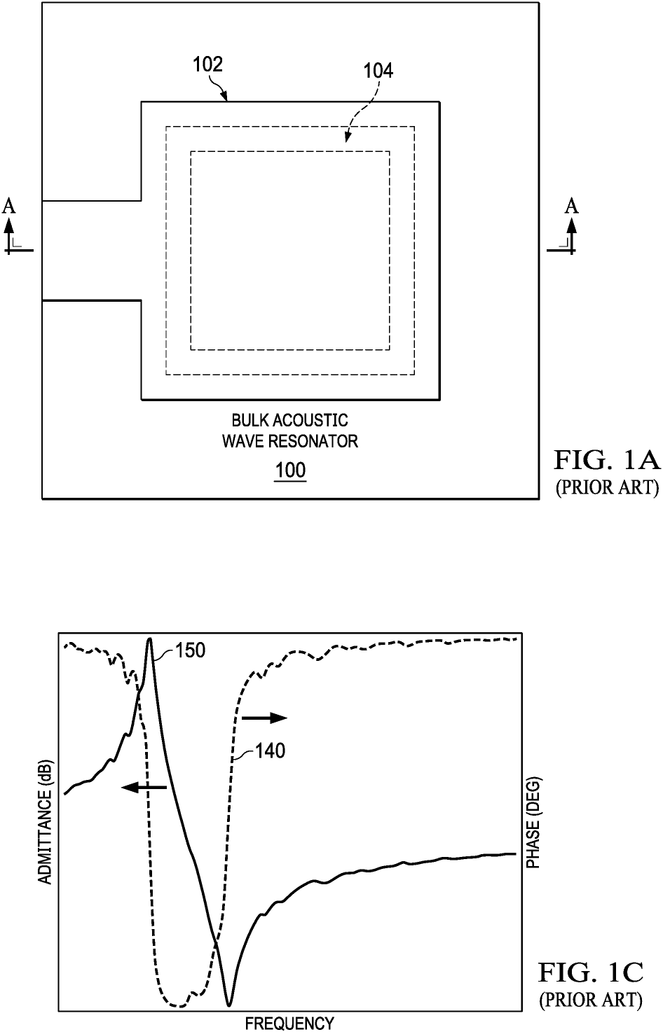

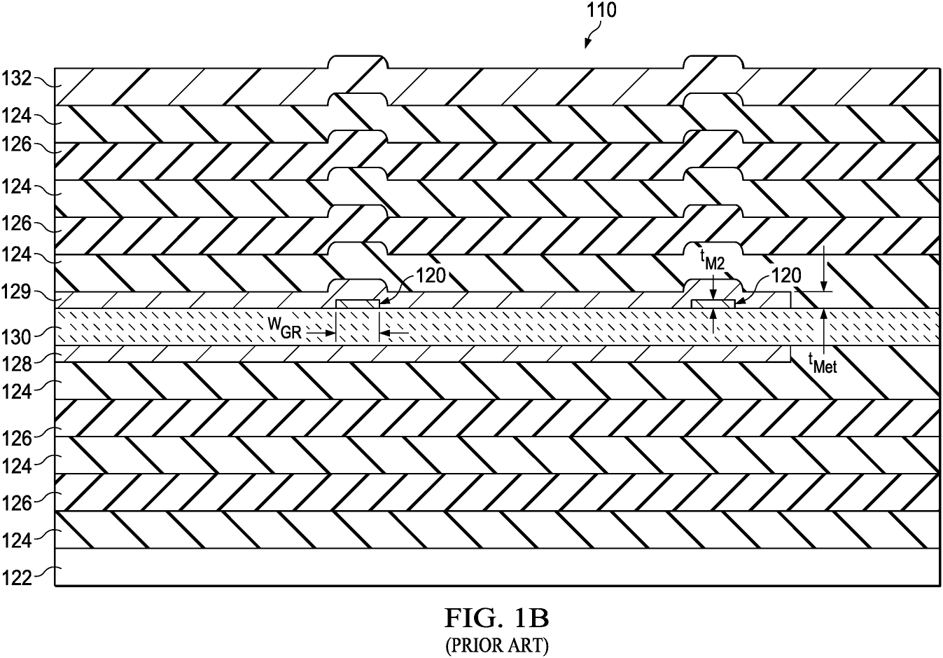

FIG. 1A illustrates a top view of a conventional BAW resonator module 100 in an example implementation. In this embodiment, BAW resonator module 100 is formed on a silicon substrate using an application specific integrated circuit (ASIC) wafer/BAW wafer, and includes conductive layer 102 and frame 104.

FIG. 1B illustrates a cross-section 110 of the conventional BAW resonator 100 of FIG. 1A along section A-A in an example implementation. In this embodiment, BAW resonator module 120 includes frame 120, substrate 122, with the BAW resonator device disposed on the substrate 122. While this example BAW resonator has a square shape, other embodiments have other shapes including rectangles, circles, ovals, polygons, and the like.

In this example, the BAW resonator 100 includes numerous layers formed on an upper (first) surface of substrate 122. In order from the substrate, these layers include low impedance material 124, high impedance material 126, low impedance material 124, high impedance material 126, low impedance material 124, first conductive layer (lower electrode) 128, piezoelectric material 130, frame 120, second conductive layer (upper electrode) 129, low impedance material 124, high impedance material 126, low impedance material 124, high impedance material 126, low impedance material 124, and cap material 132.

The alternating layers of low impedance material 124 and high impedance material 126 create acoustic (Bragg) reflectors above and below the BAW resonator device. In example embodiments, first conductive layer 128 and second conductive layer 129 comprise metal layers.

FIG. 1C illustrates the frequency response of the conventional BAW resonator 100 from FIG. 1A in an example implementation. FIG. 1C illustrates the phase 140 in degrees and admittance 150 in dB across a range of frequencies for the conventional BAW resonator 100 from FIG. 1A. This frequency response illustrates spurious modes in between the two resonances.

In order to reduce these spurious modes, stair step frame structures are used in place of the conventional frame structures illustrated in FIGS. 1A and 1B. These stair step frame structures are formed by depositing materials above the piezoelectric layer. In some examples, these frames are constructed by depositing materials in method steps that are easier to fabricate than other materials used within the BAW resonator. In these examples, the frames do not need to maintain the same material properties as the higher quality, but more difficult to fabricate material, used for the upper conductive layer (top electrode).

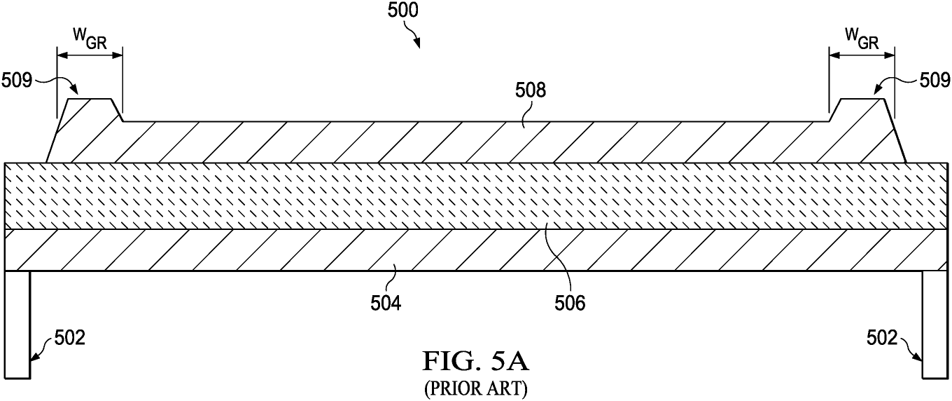

In various examples, the stair step frame structures are fabricated by depositing a variety of materials in one or more steps that are easier to fabricate with than other materials used in construction of a BAW resonator. In examples, the stair step frame design is repeated concentrically and with any number of steps. Each step of the stair and the spacing between the stair and the next stair or to the edge of the upper electrode is designed in such a way as to contain energy within the resonator. By not having the edge of the frame coincide with the ring (or outer edge of the upper electrode) and designing this final distance into a structure, less precision with the frame placement is required. In some examples, such as illustrated in FIG. 4B, the piezoelectric material is etched to a desired step thickness and this edge of the piezoelectric material is used to create the stair step.

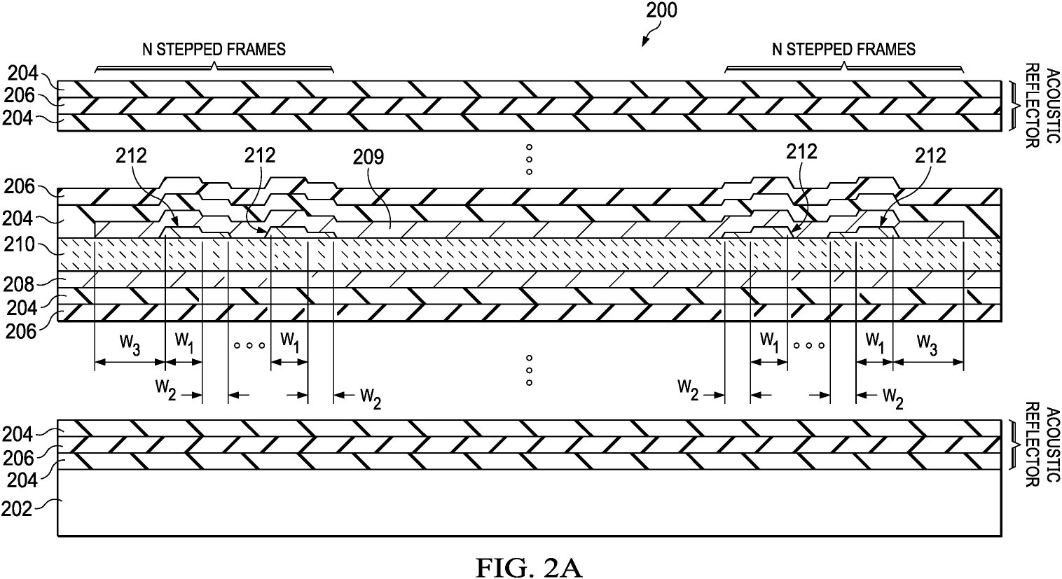

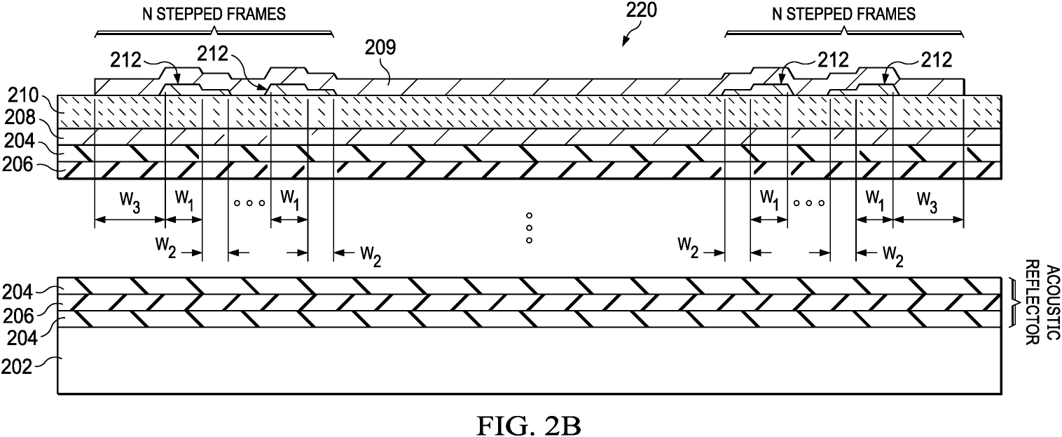

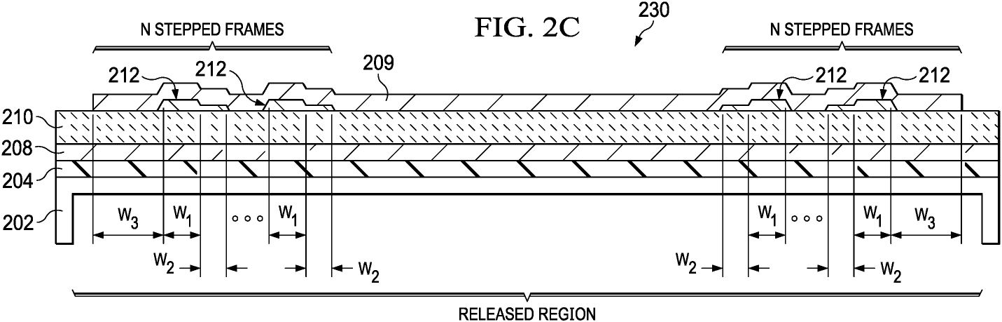

FIG. 2A illustrates a cross-section of a DBAR resonator 200 including two concentric stair stepped frames in an example implementation. In this embodiment, DBAR resonator 200 includes a silicon substrate using an application specific integrated circuit (ASIC) wafer/BAW wafer 202, along with DBAR resonator device 200 disposed on substrate 202. In this example, the DBAR resonator 200 includes numerous layers formed on an upper (first) surface of substrate 202. In order from the substrate, these layers include low impedance material 204, high impedance material 206, low impedance material 204, high impedance material 206, low impedance material 204, first conductive layer (lower electrode) 208, piezoelectric material 210, frame 212, second conductive layer (upper electrode) 209, low impedance material 204, high impedance material 206, low impedance material 204, high impedance material 206, and low impedance material 204.

In this example, DBAR resonator 200 includes two concentric stair step frames 212. Both stair step frames 212 illustrated in this example embodiment have an inner portion having width W₂ and an outer portion having width W₁. Here, the inner portion of each frame 212 has a thickness which is less than a thickness of the outer portion of each frame. Also, the two concentric stair step frames 212 are overlapped by a quantity of the second conductive layer (upper electrode) 209 having a width of W₃. Other example embodiments include stair step frames 212. Still further embodiments include stair step frames 212 having multiple steps within each frame. Other embodiments include any number of concentric stair step frames 212, each having any number of steps within each frame.

The alternating layers of low impedance material 204 and high impedance material 206 create acoustic (Bragg) reflectors above and below the BAW resonator device. In example embodiments, first conductive layer 208 and second conductive layer 209 comprise metal layers.

FIG. 2B illustrates a cross-section of a SMR resonator 220 including two concentric stair stepped frames in an example implementation. In this embodiment, SMR resonator 220 includes a silicon substrate using an application specific integrated circuit (ASIC) wafer/BAW wafer 202, along with SMR resonator device 220 disposed on substrate 202. In this example, the SMR resonator 220 includes numerous layers formed on an upper (first) surface of substrate 202. In order from the substrate, these layers include low impedance material 204, high impedance material 206, low impedance material 204, high impedance material 206, low impedance material 204, first conductive layer (lower electrode) 208, piezoelectric material 210, frame 212, and second conductive layer (upper electrode) 209.

In this example, SMR resonator 220 includes two concentric stair step frames 212. Both stair step frames 212 illustrated in this example embodiment have an inner portion having width W₂ and an outer portion having width W₁. Here, the inner portion of each frame 212 has a thickness which is less than a thickness of the outer portion of each frame. Also, the two concentric stair step frames 212 are overlapped by a quantity of the second conductive layer (upper electrode) 209 having a width of W₃. Other example embodiments include stair step frames 212. Still further embodiments include stair step frames 212 having multiple steps within each frame. Other embodiments include any number of concentric stair step frames 212, each having any number of steps within each frame.

The alternating layers of low impedance material 204 and high impedance material 206 create an acoustic (Bragg) reflector below the BAW resonator device. In example embodiments, first conductive layer 208 and second conductive layer 209 comprise metal layers.

FIG. 2C illustrates a cross-section of a FBAR resonator 230 including two concentric stair stepped frames in an example implementation. In this embodiment, FBAR resonator 230 includes a silicon substrate using an application specific integrated circuit (ASIC) wafer/BAW wafer 202 having a released region, along with FBAR resonator device 230 disposed on substrate 202. In this example, the FBAR resonator 230 includes numerous layers formed on an upper (first) surface of substrate 202. In order from the substrate, these layers include low impedance material 204, first conductive layer (lower electrode) 208, piezoelectric material 210, frame 212, and second conductive layer (upper electrode) 209.

In this example, FBAR resonator 230 includes two concentric stair step frames 212. Both stair step frames 212 illustrated in this example embodiment have an inner portion having width W₂ and an outer portion having width W₁. Here, the inner portion of each frame 212 has a thickness which is less than a thickness of the outer portion of each frame. Also, the two concentric stair step frames 212 are overlapped by a quantity of the second conductive layer (upper electrode) 209 having a width of W₃. Other example embodiments include concentric stair step frames 212. Still further embodiments include stair step frames 212 having multiple steps within each frame. Other embodiments include any number of concentric stair step frames 212, each having any number of steps within each frame.

In example embodiments, first conductive layer 208 and second conductive layer 209 comprise metal layers.

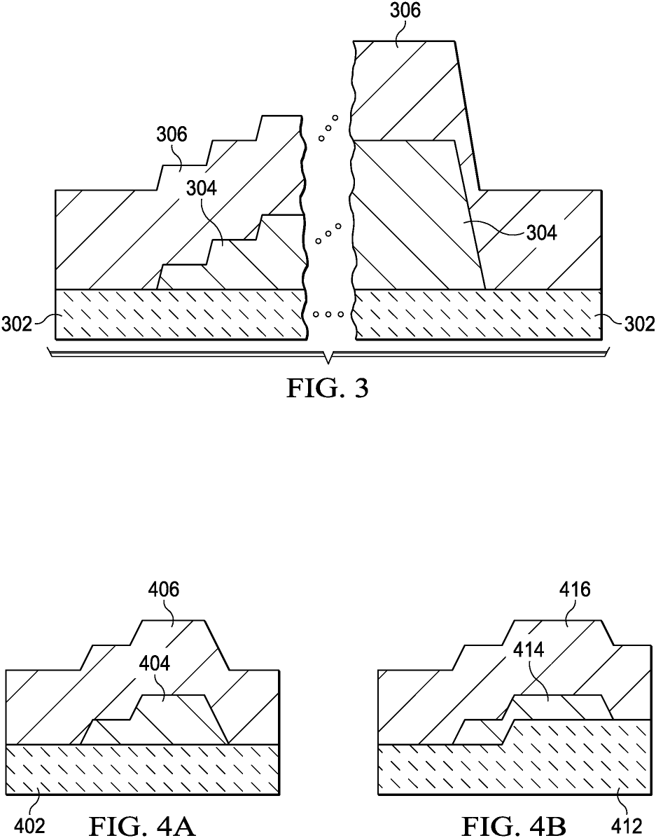

FIG. 3 illustrates a cross-section of an example stair step frame 304 within a BAW resonator including multiple steps. In this example, stair step frame 304 is formed above piezoelectric layer 302, then upper conductive layer 306 is formed above stair step frame 304. In this example, multiple stair steps are constructed within a single stair step frame 304. The number of steps within any stair step frame 304 is limited by the number of mask layers desired, as each step usually has an additional mask for implementation.

FIG. 4A illustrates a cross-section of an example stair step frame 404 within a BAW resonator including a single step. In this example, stair step frame 404 is formed on a first (upper) surface of piezoelectric material 402, then second conductive layer 406 is formed over stair step frame 404 and piezoelectric material 402.

FIG. 4B illustrates a cross-section of an example stair step frame 414 within a BAW resonator including a single step formed by etching the piezoelectric layer 412 before forming the stair step frame 414 on a first (upper) surface of piezoelectric layer 412. In this example, piezoelectric material 412 is masked and etched to form a step before frame 414 is formed. When frame 414 is formed over the step within piezoelectric layer 412 it forms a step and functions as a stair step frame 414 when second conductive layer 416 is formed over it and piezoelectric layer 412.

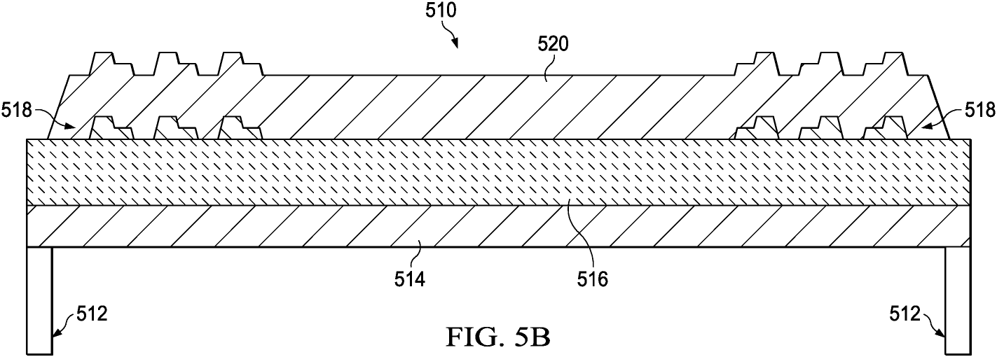

FIG. 5A illustrates a cross-section of a conventional FBAR 500 including a frame 509. In this example, a conventional FBAR 500 includes a substrate 502 supporting a first conductive layer (lower electrode) 504, a piezoelectric layer 506, and a second conductive layer (upper electrode) 508. The second conductive layer includes a frame (also known as a guard ring) 509 having a width of W_{GR}. In this example the frame coincides with the ring (or outer edge of the upper electrode).

FIG. 5B illustrates a cross-section of an FBAR 510 including multiple concentric stair stepped frames 518. In this example, an improved FBAR 510 includes a substrate 512 supporting a first conductive layer (lower electrode) 514, a piezoelectric layer 516, multiple concentric stair stepped frames 518, and a second conductive layer (upper electrode) 520.

In this example, FBAR resonator 510 includes three concentric stair step frames 518. All three stair step frames 518 illustrated in this example embodiment have an inner portion and an outer portion. Here, the inner portion of each frame 518 has a thickness which is less than a thickness of the outer portion of each frame. Also, the three concentric stair step frames 518 are overlapped by a quantity of the second conductive layer (upper electrode) 520. Other example embodiments include concentric stair step frames 518. Still further embodiments include stair step frames 518 having multiple steps within each frame. Other embodiments include any number of concentric stair step frames 518, each having any number of steps within each frame.

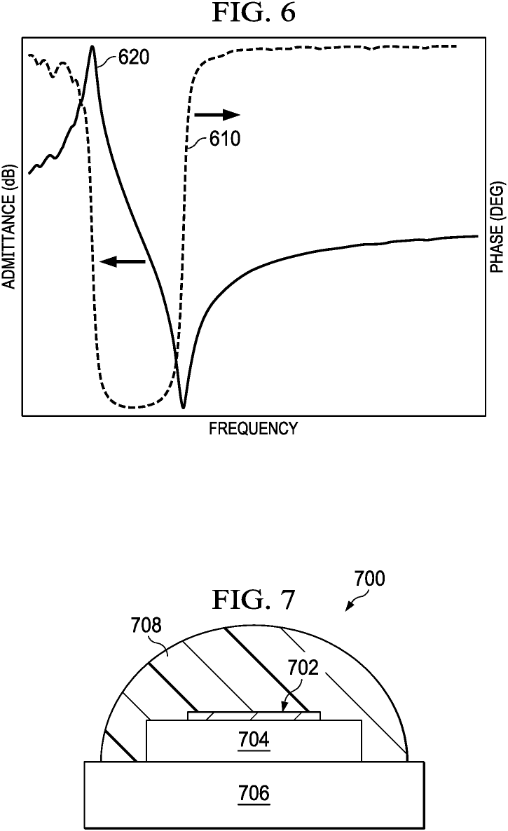

FIG. 6 illustrates the frequency response of an example BAW resonator including stair step frames. FIG. 6 illustrates the phase 610 in degrees and admittance 620 in dB across a range of frequencies for an example BAW resonator including one or more stair step frames. Comparing this frequency response to the frequency response of a conventional BAW resonator as illustrated in FIG. 1C, this frequency response illustrates a reduction in spurious modes in between the two resonances.

This frequency response illustrates the effect of the stair step frame structure in improving confinement of energy into the main mode of the resonator, resulting in fewer spurious modes and generally a cleaner response as illustrated in FIG. 6. The reduction of spurious modes accompanies an increase in the quality factor (Qₚ) of the device.

FIG. 7 illustrates a BAW resonator module 700 in an example implementation. In this example embodiment, BAW resonator 702 is encapsulated within a package including package substrate 706, BAW substrate 704, and encapsulant 708.

BAW resonator module 700 includes encapsulant 708 covering BAW resonator device 702 and BAW substrate 704. In this example, encapsulant 708 acts as a wafer-level encapsulation with respect to substrate 706. Other example embodiments include various other packaging techniques and materials. FIG. 7 illustrates one example of a BAW resonator module 700 including a package.

Encapsulant 708 is preferably an inexpensive plastic molding compound deposited over a spin-on glass passivation layer. The molding compound may be of the type used for encapsulating integrated circuit dies and which is brought into a fluid state, deposited from a reservoir onto BAW resonator device 702 and BAW substrate 704, then cured in place. It may, for example, be an epoxy novolac-based resin or other epoxy, polyimide or silicone resin deposited using a reactive polymer processing technique. Reactive polymer processing is the combined polymerization and processing of reactive polymers or prepolymers in a single operation, and encompasses numerous processing methods such as transfer molding (viz. compressing a heated preform in a mold cavity), conformal spread coating (viz. spinning, spraying, vapor deposition), radial-spread (or “glob top”) coating (viz. dispensing glob of material from a hollow needle), and reaction-injection molding (combining two-part reactive polymers into a mold cavity).

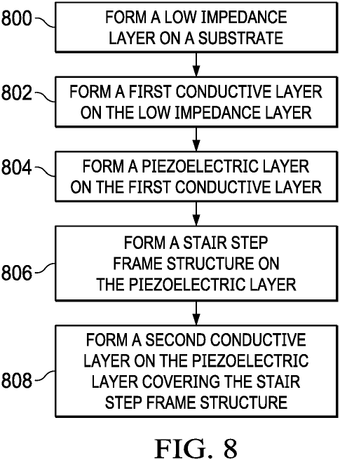

FIG. 8 illustrates a flow chart of a method of forming a piezoelectric resonator in an example implementation. In this example embodiment, a low impedance layer 204 is formed on a substrate 202, (operation 800). A first conductive layer (lower electrode) 208 is formed on the low impedance layer, (operation 802).

A piezoelectric layer 210 is formed on the first conductive layer (lower electrode) 208, (operation 804). A stair step frame structure 212 is formed on the piezoelectric layer 210, (operation 806). A second conductive layer (upper electrode) 209 is formed on the piezoelectric layer 210 covering the stair step frame structure 212, (operation 808).

Modifications are possible in the described examples, and other examples are possible within the scope of the claims.

What is claimed is:

1. A piezoelectric resonator, comprising:
a first conductive layer;
a piezoelectric layer affixed to a first side of the first conductive layer;
a stair step frame structure affixed to a first side of the piezoelectric layer; and
a second conductive layer, affixed to the first side of the piezoelectric layer and covering the stair step frame structure.

2. The piezoelectric resonator of claim 1, wherein:
the stair step frame structure has an inner portion and an outer portion;
the inner portion of the stair step frame structure has a first thickness; and
the outer portion of the stair step frame structure has a second thickness different from the first thickness.

3. The piezoelectric resonator of claim 2, wherein the first thickness is less than the second thickness.

4. The piezoelectric resonator of claim 1, wherein the stair step frame structure is a first stair step frame structure and the piezoelectric resonator further includes a second stair step frame structure affixed to the first side of the piezoelectric layer concentric with the first stair step frame structure.

5. The piezoelectric resonator of claim 1, wherein the stair step frame structure comprises two or more stair steps.

6. The piezoelectric resonator of claim 1, wherein the piezoelectric resonator is a solidly mounted resonator (SMR), and further comprises:
a substrate; and
an acoustic reflector affixed to a first side of the substrate and positioned below a second side of the first conductive layer.

7. The piezoelectric resonator of claim 1, wherein the piezoelectric resonator is a dual-Bragg acoustic resonator (DBAR), and further comprises:
a substrate;
a first acoustic reflector affixed to a first side of the substrate and positioned below a second side of the first conductive layer; and
a second acoustic reflector positioned above a first side of the second conductive layer.

8. The piezoelectric resonator of claim 1, wherein the piezoelectric resonator is a film bulk acoustic resonator (FBAR), and further comprises a substrate having a released region positioned below a second side of the first conductive layer.

9. A method of forming a piezoelectric resonator comprising:
forming a low impedance layer on a substrate;
forming a first conductive layer on the low impedance layer;
forming a piezoelectric layer on the first conductive layer;
forming a stair step frame structure on the piezoelectric layer; and
forming a second conductive layer, on the piezoelectric layer covering the stair step frame structure.

10. The method of claim 9, wherein:
the stair step frame structure has an inner portion and an outer portion;
the inner portion of the stair step frame structure has a first thickness; and
the outer portion of the stair step frame structure has a second thickness different from the first thickness.

11. The method of claim 10, wherein the first thickness is less than the second thickness.

12. The method of claim 9, wherein the stair step frame structure is a first stair step frame structure, and the method further includes forming a second stair step frame structure on the piezoelectric layer concentric with the first stair step frame structure.

13. The method of claim 9, wherein the stair step frame structure comprises two or more stair steps.

14. The method of claim 9, further comprising forming an acoustic reflector between the low impedance layer and the first conductive layer.

15. The method of claim 9, further comprising:
forming a first acoustic reflector between the low impedance layer and the first conductive layer; and
forming a second acoustic reflector on the second conductive layer.

16. The method of claim 9, wherein the substrate has a released region.

17. A bulk acoustic wave resonator (BAW) module comprising:
a package; and
a piezoelectric resonator within the package, the piezoelectric resonator comprising:
a first conductive layer;
a piezoelectric layer affixed to a first side of the first conductive layer;
a stair step frame structure affixed to a first side of the piezoelectric layer; and
a second conductive layer, affixed to the first side of the piezoelectric layer and covering the stair step frame structure.

18. The bulk acoustic wave resonator (BAW) module of claim 17, wherein the piezoelectric resonator is a solidly mounted resonator (SMR), and further comprises:
a substrate; and
an acoustic reflector affixed to a first side of the substrate and positioned below a second side of the first conductive layer.

19. The bulk acoustic wave resonator (BAW) module of claim 17, wherein the piezoelectric resonator is a dual-Bragg acoustic resonator (DBAR), and further comprises:
a substrate;
a first acoustic reflector affixed to a first side of the substrate and positioned below a second side of the first conductive layer; and
a second acoustic reflector positioned above a first side of the second conductive layer.

20. The bulk acoustic wave resonator (BAW) module of claim 17, wherein the piezoelectric resonator is a film bulk acoustic resonator (FBAR), and further comprises a substrate having a released region positioned below a second side of the first conductive layer.
